(19) United States
(12) Patent Application Publication
(10) Pub. No.: US 2022/0138570 A1
(43) Pub. Date: May 5, 2022

(54) Trust-Region Method with Deep Reinforcement Learning in Analog Design Space Exploration

(71) Applicant: MediaTek Inc., Hsinchu (TW)

(72) Inventors: Chia-Yu Tsai, Hsinchu (TW); Hung-Hao Shen, Hsinchu (TW); Chen-Feng Chiang, Hsinchu (TW); Chung-An Wang, Hsinchu (TW); Yiju Ting, Hsinchu (TW); Chia-Shun Yeh, Hsinchu (TW); Chin-Tang Lai, Hsinchu (TW); Feng-Ming Tsai, Hsinchu (TW); Kai-En Yang, Hsinchu (TW)

(21) Appl. No.: 17/495,489

(22) Filed: Oct. 6, 2021

Related U.S. Application Data
(60) Provisional application No. 63/109,890, filed on Nov. 5, 2020.

(51) Int. Cl. G06N 3/08

(52) U.S. Cl. CPC G06N 3/08

(57) ABSTRACT

A system performs the operations of a neural network agent and a circuit simulator for analog circuit sizing. The system receives an input indicating a specification of an analog circuit and design parameters. The system iteratively searches a design space until a circuit size is found to satisfy the specification and the design parameters. In each iteration, the neural network agent calculates measurement estimates for random sample generated in a trust region, which is a portion of the design space. Based on the measurement estimate, the system identifies a candidate size that optimizes a value metric. The circuit simulator receives the candidate size and generates a simulation measurement. The system calculates updates to weights of the neural network agent and the trust region for a next iteration based on, at least in part, the simulation measurement.

### CROSS-REFERENCE TO RELATED APPLICATIONS

This application claims the benefit of U.S. Provisional Application No. 63/109,890 filed on Nov. 5, 2020, the entirety of which is incorporated by reference herein.

### TECHNICAL FIELD

Embodiments of the invention relate to analog design space search using deep reinforcement learning.

### BACKGROUND

The annual increment of computing power described by Moore's law is pioneering unprecedented possibilities. This remarkable progress has been accompanied by collinearity with tremendous increases in chip design complexity. One example of this complexity is the growth in the process, voltage, and temperature (PVT) conditions. Although the majority of a system-on-a-chip (SoC) area is occupied by digital circuitry, analog circuits are essential for the chip to communicate with and sense the rest of the world. However, the design effort of the analog counterpart is more onerous due to the required intervention of human expertise and scarcity of automation tools.

Transistor sizing is a labor-intensive and time-consuming task in analog design. Currently, transistor sizing is mostly done by trial and error. The designers begin by applying their knowledge about the characteristics of analog circuits and transistors to select a reasonable range of candidate solutions. Afterwards, the designers explore the design space with a grid search and receive feedback from SPICE (Simulation Program with Integrated Circuit Emphasis) circuit simulations. The procedure of the designers' actions and SPICE circuit simulations is repeated until the specifications are met. Due to the very large design space, known techniques for automating transistor sizing often suffer from convergence problems or scalability issues.

Known circuit sizing solutions, such as Bayesian optimization (BO), model-free agents, sequence-to-sequence modeling using an encoder-decoder technique, graph convolutional neural networks, etc., suffer from various types of drawbacks such as scalability, general feasibility, efficiency, and reusability.

Furthermore, to guarantee that a chip can work under variations of fabrication processes, power supplies, and environments, a number of PVT conditions have to be signed off before tape-out. A conventional strategy for exploring the PVT conditions is to test all PVT conditions every time a new set of circuit sizing assignments is obtained. This strategy is wasteful of computing resources and electronic design automation (EDA) tool licenses.

Thus, improvement to analog sizing automation is needed to address the existing problems.

### SUMMARY

In one embodiment, a method is provided for analog circuit sizing. The method includes the steps of: receiving an input indicating a specification of an analog circuit and a plurality of design parameters; and iteratively searching a design space until a circuit size is found to satisfy the specification and the design parameters. The iteratively searching further includes the steps of: calculating, by a neural network agent, a measurement estimate for each of a plurality of samples randomly generated in a trust region to identify a candidate size that optimizes a value metric, where the trust region is a portion of the design space; and calculating updates to weights of the neural network agent and the trust region for a next iteration based on, at least in part, a simulation measurement by a circuit simulator on the candidate size.

In another embodiment, a system includes processors and a memory coupled to the processors. The memory stores instructions which, when executed by the processors, cause the processors to perform operations of a neural network agent and a circuit simulator for analog circuit sizing. The processors are operative to: receive an input indicating a specification of an analog circuit and a plurality of design parameters; and iteratively search a design space until a circuit size is found to satisfy the specification and the design parameters. The processors are further operative to: calculate, using the neural network agent, a measurement estimate for each of a plurality of samples randomly generated in a trust region to identify a candidate size that optimizes a value metric, where the trust region is a portion of the design space; and calculate updates to weights of the neural network agent and the trust region for a next iteration based on, at least in part, a simulation measurement by the circuit simulator on the candidate size.

Other aspects and features will become apparent to those ordinarily skilled in the art upon review of the following description of specific embodiments in conjunction with the accompanying figures.

### BRIEF DESCRIPTION OF THE DRAWINGS

The present invention is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one. Further, when a particular feature, structure, or characteristic is described in connection with an embodiment, it is submitted that it is within the knowledge of one skilled in the art to effect such feature, structure, or characteristic in connection with other embodiments whether or not explicitly described.

FIG. 1 illustrates a model-based RL framework for analog circuit sizing according to one embodiment.

FIG. 2 is a flow diagram illustrating a circuit sizing process according to one embodiment.

FIG. 3 is a diagram of an algorithm for exploring feasible circuit sizes according to one embodiment.

FIG. 4 is a diagram illustrating a model-based RL platform according to one embodiment.

FIG. 5 is a flow diagram illustrating a PVT exploration process according to one embodiment.

FIG. 6 illustrates an example of a PVT exploration strategy according to one embodiment.

FIG. 7 is a flow diagram illustrating a method for analog circuit sizing according to one embodiment

FIG. 8 is a diagram illustrating a system according to one embodiment.

### DETAILED DESCRIPTION

In the following description, numerous specific details are set forth. However, it is understood that embodiments of the invention may be practiced without these specific details. In other instances, well-known circuits, structures, and techniques have not been shown in detail in order not to obscure the understanding of this description. It will be appreciated, however, by one skilled in the art, that the invention may be practiced without such specific details. Those of ordinary skill in the art, with the included descriptions, will be able to implement appropriate functionality without undue experimentation.

Analog circuit sizing, also referred to as transistor sizing, is an iterative process for determining the values of a set of sizing variables, such as the length, width, and multiplicities for each transistor in a given topology to satisfy a given specification. There are usually trade-offs among design choices. For example, larger transistor sizes typically lead to greater performance but consume more power and area.

A model-based reinforcement learning (RL) framework is disclosed for analog circuit sizing. The framework automates analog circuit sizing under design constraints and incorporates a PVT exploration strategy. The framework includes RL agents, which can quickly adapt to an environment based on learned experiences and can evolve to approach optimality over time.

One aspect of the framework explores PVT conditions with high efficiency. At the system level, the framework increases R&D productivity during analog front-end sizing. Experiment results demonstrate that RL agents in the framework can efficiently search the design space of state-of-the-art designs with superior performance. At the algorithm level, the framework can directly mimic the dynamics of a circuit simulator, such as the SPICE simulator. At the verification level, the framework explores the input PVT conditions and verifies that a chosen circuit size satisfies the specification for all of the input PVT conditions.

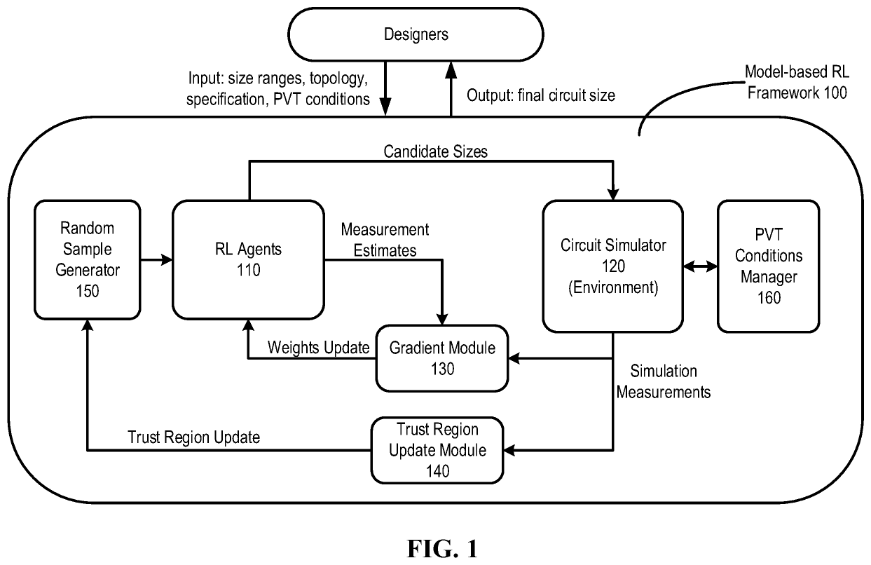

FIG. 1 illustrates a model-based RL framework 100 (“framework 100”) for analog circuit sizing according to one embodiment. The framework 100 includes one or more RL agents 110 interacting with a circuit simulator 120, such as a SPICE simulation environment (also referred to as a SPICE simulator). Each RL agent 110 is a neural network that learns by deep reinforcement learning during an iterative process. Each RL agent 100 is a model-based agent, as it is initially trained by supervised learning in a local area that is a portion of the design space. This local area is identified by the circuit simulator 120 at initialization to potentially contain a circuit size meeting the specification, and is dynamically updated during the iterations. The local area is also referred to as the trust region.

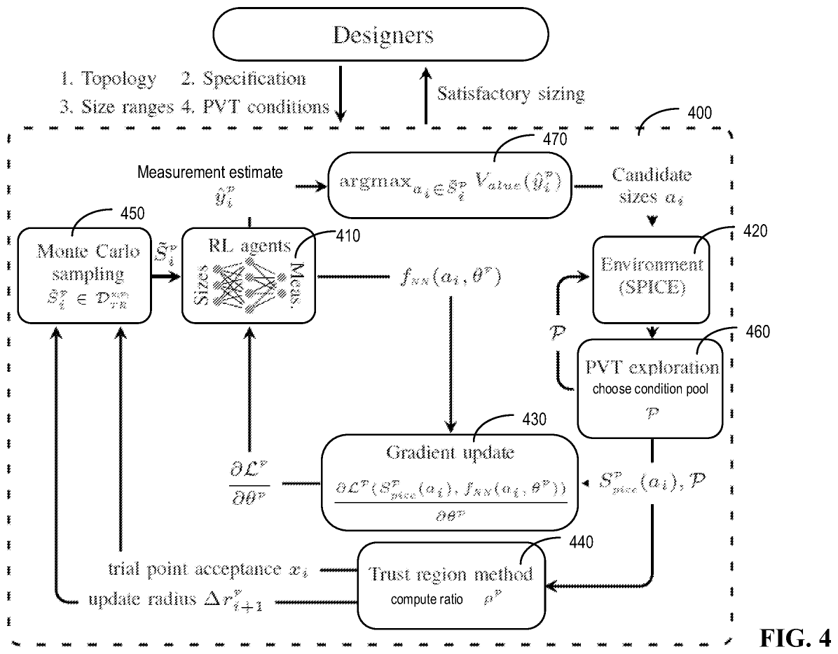

In one embodiment, the designers' input to the framework 100 includes a topology, a specification, transistor size ranges, and PVT conditions. The topology, transistor size ranges, and PVT conditions are collectively referred to as a set of design parameters. The term “designers” as used herein refers to design engineers. The framework 100 may initialize multiple RL agents, with each RL agent for a different PVT condition. To simplify the description, the scenario of multiple RL agents is described later with reference to FIGS. 4-6. The following description with reference to FIGS. 1-3 focuses on the scenario of one RL agent under one PVT condition.

A design space is the space of all sizing values that may be chosen to size an analog circuit. Thus, the circuit sizing problem is a search problem in a given design space. Each sample in the design space is a vector of sizing variables with respective sizing values. For each sample in the design space, the RL agent 110 calculates a measurement estimate, which estimates the simulation measurement of the circuit simulator 120. The RL agent 110 can generate a measurement estimate much faster than the circuit simulator 120 generates a simulation measurement.

The search problem is solved iteratively. In each iteration, the platform 100 applies a value function to each measurement estimate generated by the RL agent 110 to obtain a corresponding value metric. The sample corresponds to the measurement estimate having the highest value metric is selected as a candidate size. The candidate size is a set of assignments; i.e., the assignments of sizing values to corresponding sizing variables. The circuit simulator 120 receives the candidate size and generates a simulation measurement to verify whether the candidate size satisfies the specification. A PVT condition manager 160 keeps track of the PVT conditions that have been verified by the circuit simulator 120 as satisfying the specification, and causes the platform 100 to initialize more RL agents for the PVT conditions that fail to meet the specification.

In one embodiment, the framework 100 further includes a gradient module 130, which calculates updates to the weights of the RL agent 110. The gradient module 130 performs the updates iteratively using a gradient method based on a loss function that measures a difference (e.g., the mean square error (MSE)) between the circuit simulator's 120 simulation measurement and the RL agent's 110 measurement estimate. The framework 100 further includes a trust region update module 140, which updates a trust region iteratively for the RL agent 110 to conduct a search. The trust region is a portion of the design space. In one embodiment, the trust region is an area of a circle centered at a candidate size with a radius that may dynamically expand or shrink in each iteration. In each iteration, the RL agent 110 receives random samples in the trust region as input, and generates measurement estimates as output. The samples may be generated by a random sample generator 150 using a Monte Carlo method. As the search for a candidate size in each iteration is confined to a trust region instead of the entire design space, the search can be performed with high speed and efficiency.

Thus, the RL agent 110 identifies a candidate size among random samples for the circuit simulator 120, and the circuit simulator 120 feeds back a simulation measurement to update the RL agent 110 and the trust region in which random samples are generated for the next iteration. The framework 100 outputs a circuit size when a candidate size is found to satisfy the specification. The circuit size is referred to as the “final circuit size” when a candidate size is found to satisfy the specification and all of the input PVT conditions.

The interactions between the RL agent 110 and the circuit simulator 120 (“agent-simulator loop”) replaces the conventional designer-simulator loop in which designers interact with a circuit simulator to fine-tune a circuit size by trial-and-error. The agent-simulator loop is much more efficient and fast than the designer-simulator loop. The RL agent 110 can efficiently identify and reject unqualified samples so that the circuit simulator 120 can focus on candidate sizes that potentially may satisfy the specification.

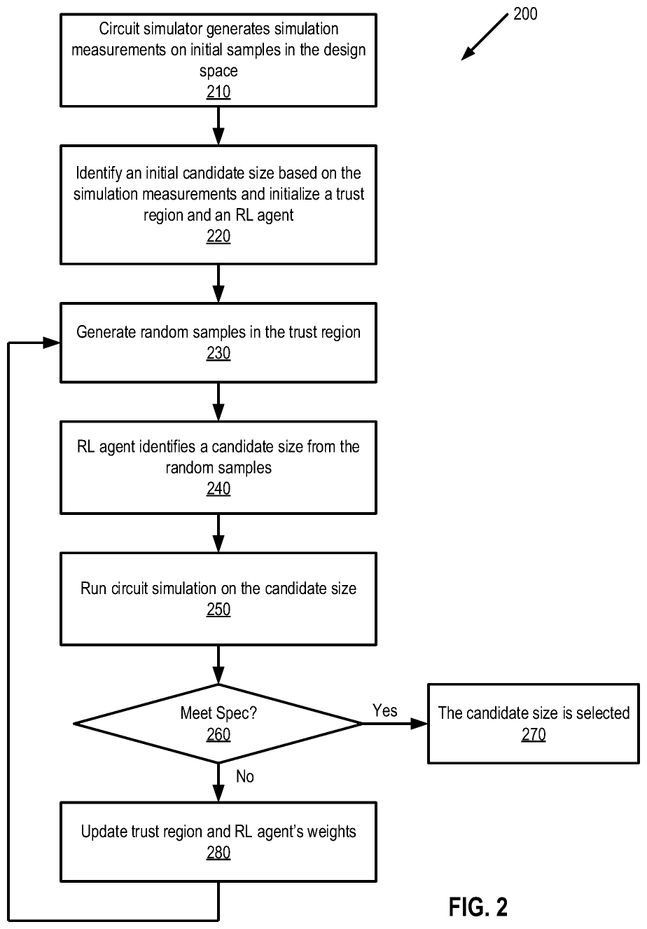

FIG. 2 is a flow diagram illustrating a circuit sizing process 200 according to one embodiment. The process 200 starts with step 210 at which a circuit simulator (e.g., the circuit simulator 120 of FIG. 1) generates simulation measurements on initial samples in the design space. Based on the simulation measurements, the platform 100 at step 220 identifies an initial candidate size among the initial samples, and initializes a trust region and an RL agent. The trust region may be a circular area centered at the initial candidate size with an initial radius. The RL agent may be initially trained with the initial candidate size and the corresponding simulation measurement. At step 230, random samples are generated in the trust region. The RL agent at step 240 identifies a candidate size from the random samples. More specifically, for each random sample, the RL agent generates a measurement estimate. The sample corresponding to the best measurement estimate (with respect to a value metric) is sent to the circuit simulator as a candidate size. At step 250, the circuit simulator runs a circuit simulation on the candidate size to obtain a simulation measurement. If the simulation measurement meets the specification at step 260, the candidate size is selected at step 270. Further verification of this selected candidate size may be performed for other PVT conditions. If the simulation measurement does not meet the specification at step 260, the trust region and the RL agent's weights are updated at step 280. The updated trust region may be centered at the candidate size identified at step 240. Then the process 200 returns to step 230 at which a new iteration begins with the updated trust region and the updated RL agent. The loop of steps 230-280 is an iterative training process that trains the RL agent in a trust region. In each iteration, the RL agent is trained with a candidate size and a corresponding simulation measurement. Experiment results show that the training is highly efficient and converges fast.

The following description provides a mathematical formulation of analog circuit sizing. Generally, analog circuit sizing can be formulated as a constrained multi-objective optimization problem, defined in (1).

Minimize F_{m,c}(X), m=1,2, . . . ,Nₘ, c=1,2, . . . ,N_{c},

subject to C_{d,c}(X)<0, d=1,2, . . . ,N_{d}, c=1,2, . . . ,N_{c}, (1)

X∈ [symbol] s

where X is a vector of variables to be optimized; [symbol] s is the design space; F_{m,c}(X) is the m^{th} objective function (e.g., power, performance, and area) under the c^{th} PVT condition; and C_{d,c}(X) is the d^{th} constraint under the c^{th} PVT condition.

With the exponential growth in PVT conditions during fast technological advances, finding the global optimal solution for (1) is often infeasible. In contrast, meeting the constraints assigned by designers is more practical. Thus, the optimization problem described in (1) can be reduced to a constraint satisfaction problem (CSP). More generally, a CSP is defined as a triple [symbol] X, [symbol] , C [symbol] in (2).

X={x₁,x₂, . . . ,xₙ}

[symbol]

={D₁,D₂, . . . ,Dₙ}, Dᵢ={b₁,b₂, . . . ,bₗ}

C={C₁,C₂, . . . ,Cₙ}, Cⱼ=(tⱼ,rⱼ) (2)

where X is a finite set of sizing variables to be searched. Each sizing variable has a non-empty domain Dᵢ, namely a design space, and {b₁, b₂, . . . , bₗ} are the possible values. C is a set of constraints. A constraint is a pair that consists of a constraint scope tⱼ and a relation rⱼ over the variables in the scope, limiting feasible permutations of assignments. The simulation performed by a circuit simulator (e.g., a SPICE simulator) is denoted as the S_{pice} function.

One effective approach for solving a CSP in (2) is a local search. Local search performed by the model-based RL framework 100 (FIG. 1) has the following three-fold advantages. I) Faster environment adaptation: reducing the domain to a local region (i.e., the trust region) allows fewer iterations for constructing the space. In addition, the circuit space is locally continuous, i.e., neighboring points around a known optimum show similar optimality. 2) Model-based agents with supervised learning: supervised learning works efficiently in a local landscape. Since no reward is involved in the training of model-based agents, the learning is insensitive to reward engineering. 3) Easier implementation and convergence: the training routine of supervised learning is relatively easy when compared with model-free agents.

The model-based RL framework 100 provides a direct modeling of a compact design space D_{L}. Imitating the behavior of a SPICE simulator, the model maps transistor sizes X to estimates of simulation measurements S_{pice}(X). In one embodiment, the model (e.g., the RL agent 110 in FIG. 1) may take the form of a feed-forward neural network f_{N,N}(X; θ) with three layers. The model can serve as a SPICE function approximator as expressed in (3).

ŷ=f_{N,N}(X;θ)≈S_{pice}(X),X∈D_{L} (3)

where ŷ is a vector of predicted measurements (e.g., gain, phase margin, etc.) with respect to a vector of sizes X estimated with weights θ.

The loss function J(θ) may be obtained by the mean squared error (MSE) as shown in (4).

$$J ( θ ) = \frac{1}{m} {\sum }_{i = 1}^{m} {( {S}_{p i c e} ( {X}^{( i )} ) - {f}_{N , N} ( {X}^{( i )} ; θ ) )}^{2} \qquad ( 4 )$$

A model-based RL agent (e.g., the RL agent 110 in FIG. 1) aims to learn a predictive model f_{N,N} to mimic the dynamics of the environment S_{pice}. The predictive model f_{N,N} is updated iteratively using a gradient method based on the loss function in (4). A model-based RL agent explores feasible solutions instead of a global solution to prevent over-designing the circuit. An RL agent is also referred to as a neural network agent.

A value function is used to evaluate the merit of simulation measurements and measurement estimates. The output of the value function is referred to as a value metric. The value function does not participate in training the RL agents and, therefore, does not affect the convergence of the neural network model. A non-limiting example of the value function (Vₐₗᵤₑ) is the sum of normalized measurements. Such a value function can be evaluated with readily available information. However, in terms of the trade-off between constraints, an alternative value function may be implemented to encode (e.g., weigh) the importance of each measurement.

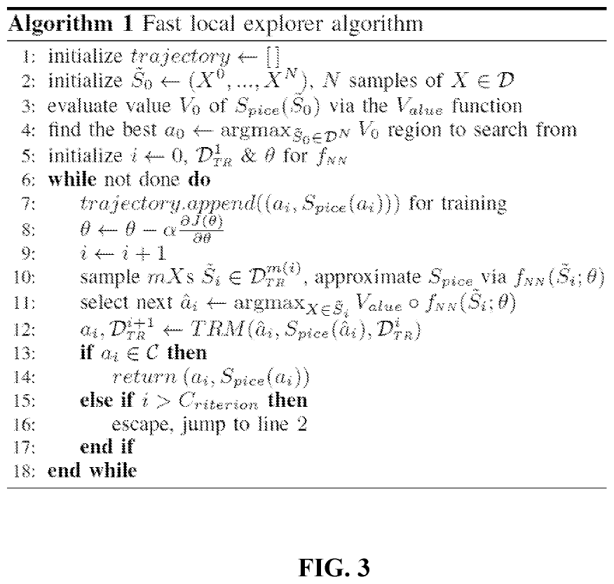

FIG. 3 is a diagram of an algorithm (in pseudocode) for exploring feasible circuit sizes according to one embodiment. The algorithm starts with a random exploration in the design space at initialization. A SPICE simulator simulates N samples in the design space, and identifies a best sample based on the value metric of the simulation measurements. The area around the best sample is selected as the local area D_{TR}. A model (i.e., a neural network agent) is constructed from exploring the local area. Monte Carlo sampling is used to randomly sample the local area, taking advantage of the fast inference time of the neural network agent. The neural network agent identifies a candidate size in the local area based on the value metric of ŷ. The SPICE simulator runs a simulation on the candidate size to generate a simulation measurement. The local area is then updated by a trust region method (TRM) for the next iteration. The weights of the neural network agent are also updated.

One key factor to the performance of the neural network agent is the transition of search space size from a global landscape to a local area. Thus, the definition of the local properties plays a role in the algorithm's efficiency. The local area, also referred to as the trust region, is dynamically updated throughout the search.

The trust region method defines an iteration-dependent trust region radius Δrⱼ where the model Vₐₗᵤₑ ∘f_{N,N} is trusted to be an adequate representation of the objective function Vₐₗᵤₑ ∘S_{pice}. At each iteration i, a trust region algorithm first solves the trust region sub-problem (5) to obtain d*⁽ⁱ⁾. In one embodiment, this is realized by Monte Carlo sampling.

D_{TR}ⁱ={X∈D|∥X−Xⁱ∥≤Δrⁱ} (5)

where d*⁽ⁱ⁾ is a vector of optimal trial steps from the current center point, ∥⋅∥ is a norm, D_{TR}ⁱ is the trust region.

The trust region method computes the ratio ρⁱ of an estimated reduction and an actual reduction. The estimated reduction is a difference between an estimate function value at the current center point of the trust region and an estimate function value at a trial point (which is trial steps away from the current center point). The estimated function value is the value metric of the measurement estimate Vₐₗᵤₑ ∘f_{N,N}. Similarly, the actual function value is the value metric of the simulation measurement Vₐₗᵤₑ ∘S_{pice}. The actual reduction is defined as a difference between an actual function value at the current center point of the trust region and an actual function value at a trial point. A trial point is accepted or denied based on the ratio ρⁱ. The radius expands if the neural network closely approximates the objective function Vₐₗᵤₑ ∘S_{pice}. A close approximation is indicated by the ratio being close to 1 (e.g., within a predetermined threshold). Otherwise, the radius shrinks. The radius update is calculated based on the ratio.

Conceptually, a trust region is a circular area characterized by a center and a radius. The center is at the best sample identified at initialization or during each iteration. The trust-region radius is dynamically changed based on the accuracy of the model in a trust region with the current radius. The aforementioned ratio is a measurement or estimate of the accuracy. The radius is chosen such that it is not too large for modeling the neural network, and not so small as to require searching more local regions. The trust-region method balances this trade-off. If the neural network can sufficiently model a trust region (i.e., closely approximates the objective function), then the radius can expand to allow searching in a larger space. If the neural network cannot sufficiently model the current trust region, then the radius is not changed or is reduced to allow for easier modeling.

In the algorithm of FIG. 3, the search for a circuit size is performed under one PVT condition. The search can be extended to multiple PVT conditions, as described below with reference to FIGS. 4-6.

FIG. 4 is a diagram illustrating a model-based RL platform 400 (“platform 400”) according to one embodiment. The platform 400 is an example of the platform 100 in FIG. 100 with further details. The platform 400 includes RL agents 410, a SPICE environment 420, a gradient update 430, a trust region method 440, Monte Carlos sampling 450, and PVT exploration 460, which are examples of the RL agents 110, the circuit simulator 120, the gradient module 130, the trust region update module 140, the random sample generator 150, and the PVT conditions manager 160, respectively.

The PVT exploration 460 maintains and updates a condition pool [symbol] as part of a PVT exploration strategy. Initially, the condition pool may include only one PVT condition, which is the worst PVT condition (i.e., the most difficult condition for an analog circuit to meet the specification according to prior knowledge or experiences) among all PVT conditions specified in the designers' input. The condition pool may progressively expand to include additional PVT conditions. Each PVT condition has its own independent model. That is, each PVT condition in the condition pool has a corresponding RL agent 410 in an agent pool, and each RL agent 410 in the agent pool is trained to model a different PVT condition in the condition pool. Multiple RL agents 410 can concurrently perform measurement estimates on the same set of random samples in the same trust region. In each iteration, the gradient update 430 updates the weights of each RL agent 410 based on an agent-specific loss function (e.g., the MSE function), and the trust region method 440 determines a common trust region for all of the RL agents 410.

In each iteration, the Monte Carlos sampling 450 generates a set of random samples in the trust region for all of the RL agents 410. Each RL agent 410 calculates a measurement estimate for each random sample. The platform 400 includes a value function module 470 that evaluates a value metric of each measurement estimate from each RL agent 410. The sample corresponding to the measurement estimate having the maximum value metric is selected as a candidate size. For a multi-agent case, each RL agent 410 in the agent pool first calculates its best candidate size. Then, the worst candidate size is chosen among all of the best candidate sizes as the candidate size and is sent to the SPICE environment 420. The “best” and the “worst” candidate sizes are chosen to maximize and minimize, respectively, the value metrics of the corresponding measurement estimates. The SPICE environment 420 runs a circuit simulation on the candidate size and the simulation measurement is used to update the RL agents 410 and the trust region. The iterative process between the RL agents 410 and the SPICE environment 420 continues until a final circuit size is found that satisfies the specification under all PVT conditions specified in the designers' input.

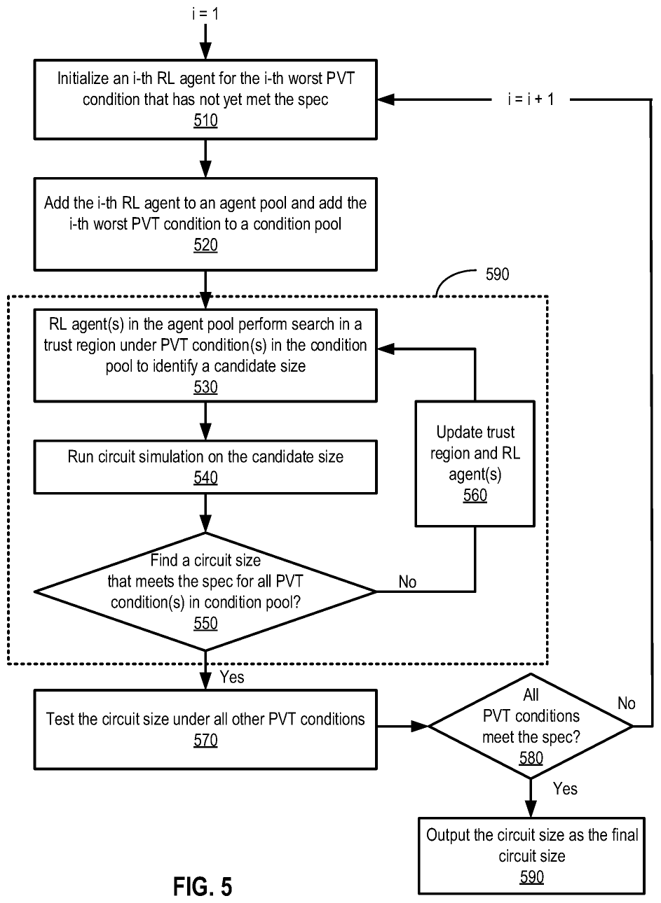

FIG. 5 is a flow diagram illustrating a PVT exploration process 500 according to one embodiment. The PVT exploration process 500 is a progressive strategy. The PVT exploration process 500 first focuses the search on a single PVT condition; e.g., the most difficult PVT condition. It is assumed that by overcoming the most difficult PVT condition, finding a circuit size under other PVT conditions may be easier. The circuit size is a set of assignments; i.e., the assignments of sizing values to corresponding sizing variables. Once a circuit size is found to satisfy the specifications, verifications are performed to confirm that the circuit size also satisfies the specification under all other PVT conditions.

Referring to FIG. 5, the PVT exploration process 500 starts with initializing, at step 510, an i-th RL agent for the i-th worst PVT condition that has not yet met the specification, where i is a running index initialized to be 1. At step 520, the i-th RL agent is added to an agent pool and the i-th worst PVT condition is added to a condition pool. At step 530, the RL agent(s) in the agent pool perform a search in a trust region under PVT condition(s) in the condition pool to identify a candidate size. At step 540, a circuit simulator runs a circuit simulation on the candidate size. If, at step 550, a circuit size is not found that meets the specification for all PVT condition(s) in the condition pool, the weights of each RL agent and the trust region are updated at step 560 and the process 500 returns to step 530 at which all RL agents in the agent pool starts another search in the updated trust region. It is noted that steps 530-560 in the dotted block 590 represent the operations of the circuit sizing process 200 (FIG. 2) performed by multiple RL agents under multiple PVT conditions.

If a circuit size is found that meets the specification for all PVT condition(s) in the condition pool, the circuit simulator at step 570 tests the circuit size under all other PVT conditions, i.e., all PVT conditions that are not in the condition pool. If, at step 580, the test indicates that all PVT conditions meet the specification, the circuit size is output as the final circuit size. If, at step 580, the test indicates that not all PVT conditions meet the specification, the process 500 returns to step 510 with an incremented index i to initialize a next RL agent for the next worst PVT condition that fails to meet the specification. The process 500 continues until the final circuit size is found.

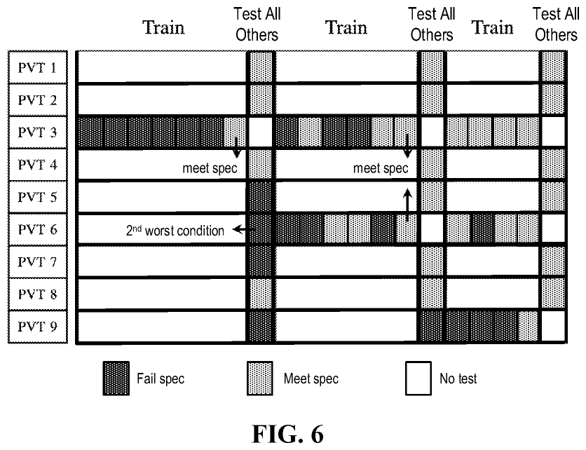

FIG. 6 illustrates an example of a PVT exploration strategy according to one embodiment. A first RL agent is initialized and trained to search for a candidate size under the worst PVT condition, namely PVT3, which is the PVT condition hardest to satisfy among the nine PVT conditions. After the first RL agent identifies a candidate size that meets the specification under PVT3, the circuit simulator tests the candidate size for all other PVT conditions. Suppose that the candidate size fails to meet the specification under PVT5, PVT6, PVT7, and PVT9, among which PVT6 is the second-worst PVT condition. A second RL agent is initialized and trained to search for a candidate size under PVT6 concurrently with the first RL agent performing a second round of the search under PVT3. After the first RL agent and the second RL agent jointly identify a second candidate size that meets the specification under both PVT3 and PVT6, the circuit simulator tests the second candidate size for all other PVT conditions.

Suppose that the second candidate size fails to meet the specification under PVT9 only. A third RL agent is initialized and trained to search for a candidate size under PVT9 concurrently with the first RL agent searching under PVT3 and the second RL agent searching under PVT6. After all three RL agents jointly identify a third candidate size that meets the specification under PVT3, PVT6, and PVT9, the circuit simulator tests the third candidate size for all other PVT conditions. Suppose that the third candidate size meets the specification under all other PVT conditions, the third candidate size is output as the final circuit size solution for the analog circuit sizing problem.

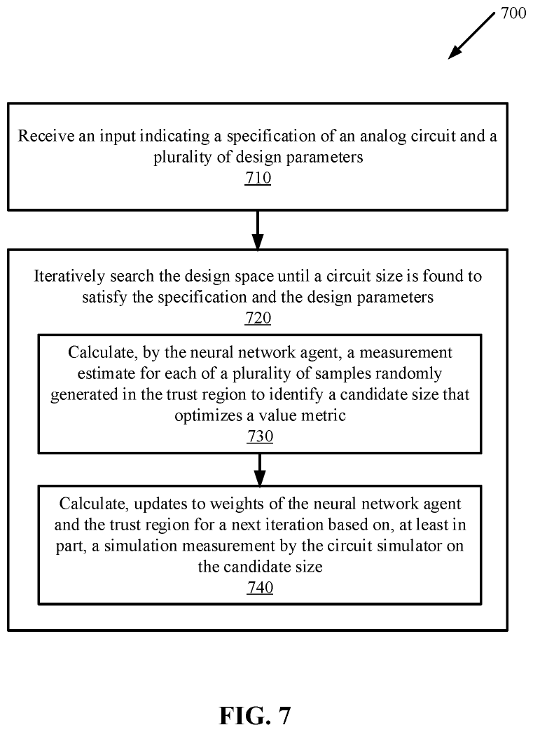

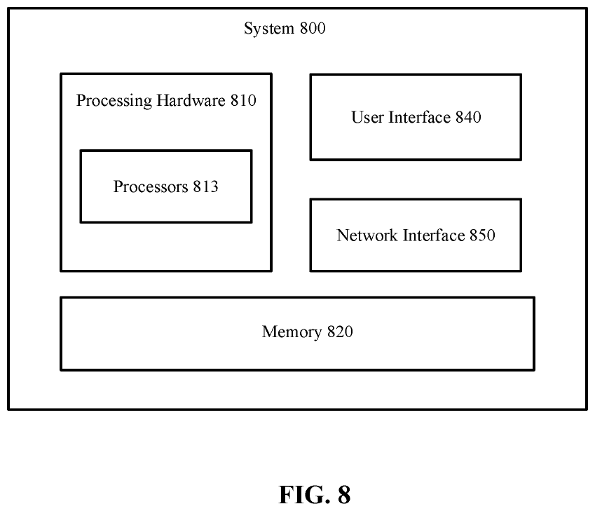

FIG. 7 is a flow diagram illustrating a method 700 for analog circuit sizing according to one embodiment. The method 700 may be performed by a system 800 in FIG. 8. The method 700 begins at step 710 when the system receives an input indicating a specification of an analog circuit and a set of design parameters. The system at step 720 iteratively searches a design space until a circuit size is found to satisfy the specification and the design parameters. The iterative search includes the following steps 730 and 740. At step 730, the neural network agent calculates a measurement estimate for each sample randomly generated in a trust region to identify a candidate size that optimizes a value metric. The trust region is a portion of the design space. At step 740, the system calculates updates to the weights of the neural network agent and the trust region for the next iteration based on, at least in part, a simulation measurement by the circuit simulator on the candidate size.

In one embodiment, the value metric at step 730 is the output of a value function applied to the measurement estimate generated by the neural network agent taking the candidate size as input.

In one embodiment, at initialization of the neural network agent, the system selects an initial candidate size that optimizes simulation measurements generated by the circuit simulator on initial samples in the design space. The system initializes a trust region centered at the initial candidate size. The system also initializes the neural network agent, which is trained with at least the initial candidate size and a corresponding simulation measurement. In one embodiment, the trust region searched in a current iteration is centered at the candidate size identified in a previous iteration.

The model-based RL frameworks 100 and 400 may be implemented on one or more processors that execute instructions to perform the methods of the frameworks 100 and 400.

FIG. 8 is a diagram illustrating a system 800 according to one embodiment. The system 800 include hardware circuits for executing the operations described in connection with FIGS. 1-7. The system 800 includes processing hardware 810. In one embodiment, the processing hardware 810 may include one or more processors 813, such as central processing units (CPUs), graphics processing units (GPUs), digital processing units (DSPs), artificial intelligence (AI) processors, and other general-purpose and/or special-purpose processing circuitry. Referring back to FIG. 1 and FIG. 4, the one or more processors 813 may execute instructions stored in a memory 820 to perform operations of the model-based RL framework 100 and/or model-based RL framework 400. The processing hardware 810 may also include non-programmable fixed-function hardware.

The memory 820 is coupled to the processing hardware 810. The memory 820 may include dynamic random access memory (DRAM), SRAM, flash memory, and other non-transitory machine-readable storage medium; e.g., volatile or non-volatile memory devices. The memory 820 may further include storage devices, for example, any type of solid-state or magnetic storage device. In one embodiment, the memory 820 may store instructions which, when executed by the processing hardware 810, cause the processing hardware 810 to perform the aforementioned analog sizing operations, such as the method 500 in FIG. 5 and the method 700 in FIG. 7.

The system 800 may also include a user interface 830 to acquire information from designers. Designers may provide input via the user interface 830 to indicate one or more of the following: transistor sizes to tune, the ranges of sizing variables, the circuit topology, the measurements to observe from SPICE simulations, and the specifications for each PVT condition. The memory 820 may store an automatic script, which when executed by the processing hardware 810, constructs the neural network agents and hyper-parameters of the neural network.

In some embodiments, the system 800 may also include a network interface 850 to connect to a wired and/or wireless network for transmitting and/or receiving voice, digital data, and/or media signals. It is understood the embodiment of FIG. 8 is simplified for illustration purposes. Additional hardware components may be included.

The operations of the flow diagrams of FIGS. 2, 5, and 7 have been described with reference to the exemplary embodiments of FIGS. 1, 4, and 8. However, it should be understood that the operations of the flow diagrams of FIGS. 2, 5, and 7 can be performed by embodiments of the invention other than the embodiments of FIGS. 1, 4, and 8, and the embodiments of FIGS. 1, 4, and 8 can perform operations different than those discussed with reference to the flow diagrams. While the flow diagrams of FIGS. 2, 5, and 7 show a particular order of operations performed by certain embodiments of the invention, it should be understood that such order is exemplary (e.g., alternative embodiments may perform the operations in a different order, combine certain operations, overlap certain operations, etc.).

Various functional components or blocks have been described herein. As will be appreciated by persons skilled in the art, the functional blocks will preferably be implemented through circuits (either dedicated circuits or general-purpose circuits, which operate under the control of one or more processors and coded instructions), which will typically comprise transistors that are configured in such a way as to control the operation of the circuitry in accordance with the functions and operations described herein.

While the invention has been described in terms of several embodiments, those skilled in the art will recognize that the invention is not limited to the embodiments described, and can be practiced with modification and alteration within the spirit and scope of the appended claims. The description is thus to be regarded as illustrative instead of limiting.

What is claimed is:

1. A method for analog circuit sizing, comprising:
receiving an input indicating a specification of an analog circuit and a plurality of design parameters; and
iteratively searching a design space until a circuit size is found to satisfy the specification and the design parameters, wherein the iteratively searching further comprises:
calculating, by a neural network agent, a measurement estimate for each of a plurality of samples randomly generated in a trust region to identify a candidate size that optimizes a value metric, wherein the trust region is a portion of the design space; and
calculating updates to weights of the neural network agent and the trust region for a next iteration based on, at least in part, a simulation measurement by a circuit simulator on the candidate size.

2. The method of claim 1, further comprising:
selecting an initial candidate size that optimizes simulation measurements generated by the circuit simulator on initial samples in the design space;
initializing the trust region centered at the initial candidate size; and
initializing the neural network agent, which is trained with at least the initial candidate size and a corresponding simulation measurement.

3. The method of claim 1, wherein the trust region searched in a current iteration is centered at the candidate size identified in a previous iteration.

4. The method of claim 1, wherein the design parameters include a plurality of process, voltage, temperature (PVT) conditions, the method further comprises:
identifying the circuit size that satisfies the specification under a worst one of the PVT conditions;
testing, by the circuit simulator, the circuit size under all of the PVT conditions except the worse PVT condition; and
progressively exploring the PVT conditions that fail the testing until a final circuit size is found to satisfy the specification and all of the PVT conditions.

5. The method of claim 4, wherein the progressively exploring further comprises:
adding, to a condition pool, a next worst PVT condition among the PVT conditions that fail the testing, wherein the condition pool initially includes the worst PVT condition;
adding, to an agent pool, a next neural network agent for the next worst PVT condition, wherein the agent pool initially includes the neural network agent for the worst PVT condition; and
iteratively searching, by the neural network agents in the agent pool, a common trust region for an updated circuit size that satisfies the specification under respective PVT conditions in the condition pool; and
incrementing the agent pool and the condition pool for the iteratively searching until the final circuit size is found to satisfy the specification and all of the PVT conditions.

6. The method of claim 1, wherein the circuit size is a solution for a constraint satisfaction problem defined by a set of constraints and a set of circuit variables, with each circuit variable corresponding to a set of predetermined sizing values.

7. The method of claim 1, wherein calculating the updates further comprises:
calculating a ratio to estimate an accuracy of the neural network agent in the trust region with respect to the simulation measurements in the trust region; and
calculating a change to a radius of the trust region based on the ratio.

8. The method of claim 1, wherein the neural network agent is a multi-layer neural network that learns by reinforcement learning.

9. The method of claim 1, wherein the value metric is an output of a value function applied to the measurement estimate generated by the neural network agent taking the candidate size as input.

10. The method of claim 1, wherein the value metric is an output of a value function that evaluates a sum of normalized measurements.

11. A system, comprising:
a plurality of processors;
a memory coupled to the plurality of processors to store instructions which, when executed by the processors, cause the processors to perform operations of a neural network agent and a circuit simulator for analog circuit sizing, wherein the processors are operative to:
receive an input indicating a specification of an analog circuit and a plurality of design parameters; and
iteratively search a design space until a circuit size is found to satisfy the specification and the design parameters, wherein the processors are further operative to:
calculate, using the neural network agent, a measurement estimate for each of a plurality of samples randomly generated in a trust region to identify a candidate size that optimizes a value metric, wherein the trust region is a portion of the design space; and
calculate updates to weights of the neural network agent and the trust region for a next iteration based on, at least in part, a simulation measurement by the circuit simulator on the candidate size.

12. The system of claim 11, wherein the processors are further operative to:
select an initial candidate size that optimizes simulation measurements generated by the circuit simulator on initial samples in the design space;
initialize the trust region centered at the initial candidate size; and
initialize the neural network agent, which is trained with at least the initial candidate size and a corresponding simulation measurement.

13. The system of claim 11, wherein the trust region searched in a current iteration is centered at the candidate size identified in a previous iteration.

14. The system of claim 11, wherein the design parameters include a plurality of process, voltage, temperature (PVT) conditions, and the processors are further operative to:
identify the circuit size that satisfies the specification under a worst one of the PVT conditions;
test, by the circuit simulator, the circuit size under all of the PVT conditions except the worse PVT condition; and
progressively explore the PVT conditions that fail the testing until a final circuit size is found to satisfy the specification and all of the PVT conditions.

15. The system of claim 14, wherein the progressively explore further comprises:
add, to a condition pool, a next worst PVT condition among the PVT conditions that fail the testing, wherein the condition pool initially includes the worst PVT condition;
add, to an agent pool, a next neural network agent for the next worst PVT condition, wherein the agent pool initially includes the neural network agent for the worst PVT condition; and
iteratively search, by the neural network agents in the agent pool, a common trust region for an updated circuit size that satisfies the specification under respective PVT conditions in the condition pool; and
increment the agent pool and the condition pool for the search until the final circuit size is found to satisfy the specification and all of the PVT conditions.

16. The system of claim 11, wherein the circuit size is a solution for a constraint satisfaction problem defined by a set of constraints and a set of circuit variables, with each circuit variable corresponding to a set of predetermined sizing values.

17. The system of claim 11, wherein the processors are further operative to:
calculate a ratio to estimate an accuracy of the neural network agent in the trust region with respect to the simulation measurements in the trust region; and
calculate a change to a radius of the trust region based on the ratio.

18. The system of claim 11, wherein the neural network agent is a multi-layer neural network that learns by reinforcement learning.

19. The system of claim 11, wherein the value metric is an output of a value function applied to the measurement estimate generated by the neural network agent taking the candidate size as input.

20. The system of claim 11, wherein the value metric is an output of a value function that evaluates a sum of normalized measurements.
